(19) United States
(12) Patent Application Publication
(10) Pub. No.: US 2024/0381699 A1
(43) Pub. Date: Nov. 14, 2024

(54) DISPLAY DEVICE

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/406,144

(22) Filed: Jan. 6, 2024

(30) Foreign Application Priority Data
May 11, 2023 (KR) 10-2023-0060916

(51) Int. Cl. H10K 59/122; H10K 59/80

(52) U.S. Cl. CPC H10K 59/122; H10K 59/873

(57) ABSTRACT

A display device includes: a pixel electrode; a pixel defining layer defining a first opening overlapping the pixel electrode; a bank structure disposed on the pixel defining layer and defining a second opening overlapping the first opening; a light emitting layer disposed on the pixel electrode; a common electrode disposed on the light emitting layer and in contact with the bank structure; and an encapsulation layer disposed on the common electrode and the bank structure. The bank structure includes: a first bank layer disposed on the pixel defining layer and including a conductive material; and a second bank layer disposed on the first bank layer and including a tip protruding toward the first opening more than a side surface of the first bank layer. The common electrode extends along the side surface of the first bank layer and is in contact with a bottom surface of the second bank layer

This application claims priority to Korean Patent Application No. 10-2023-0060916, filed on May 11, 2023, and all the benefits accruing therefrom under 35 U.S.C. § 119, the content of which in its entirety is herein incorporated by reference.

### BACKGROUND

### 1. Technical Field

The present disclosure relates to a display device.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

Aspects of the present disclosure provide a display device capable of improving defects due to oxygen or moisture introduced from outside.

Aspects of the present disclosure also provide a display device capable of improving defects due to film lifting between a bank structure and an encapsulation layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

An embodiment of a display device includes: a substrate; a first pixel electrode disposed on the substrate; a pixel defining layer disposed on the substrate and defining a first opening overlapping the first pixel electrode in a plan view; a bank structure disposed on the pixel defining layer and defining a second opening overlapping the first opening in the plan view; a first light emitting layer disposed on the first pixel electrode in the first opening; a first common electrode disposed on the first light emitting layer in the second opening and in contact with the bank structure; and a first encapsulation layer disposed on the first common electrode and the bank structure, where the bank structure includes: a first bank layer disposed on the pixel defining layer and including a conductive material; and a second bank layer disposed on the first bank layer and including a tip protruding toward the first opening more than a side surface of the first bank layer, and the first common electrode extends along the side surface of the first bank layer and is in contact with one surface of the second bank layer facing the first bank layer.

In an embodiment, the side surface of the first bank layer may include a first portion in contact with the first common electrode and a second portion in contact with the first light emitting layer, where an entirety of the side surface of the first bank layer may be divided into the first portion in contact with the first common electrode and the second portion in contact with the first light emitting layer.

In an embodiment, an area of the first portion of the first bank layer in contact with the first common electrode may be greater than ab area of the second portion of the first bank layer in contact with the first light emitting layer.

In an embodiment, a display device may further comprise a capping layer completely covering a first portion of the first common electrode overlapping the first opening in the plan view, and in the plan view the capping layer expose a second portion of the first common electrode in the second opening, and the second portion of the first common electrode exposed by the capping layer may contact the first encapsulation layer.

In an embodiment, a thickness of the first bank layer in a thickness direction may be greater than a thickness of the second bank layer.

In an embodiment, a display device may further comprise a first organic pattern disposed to surround the first opening on the second bank layer of the bank structure and including the same material as the first light emitting layer, wherein the first organic pattern is spaced apart from the first light emitting layer.

In an embodiment, a display device may further comprise a first electrode pattern completely covering the first organic pattern in an area overlapping the second opening in the plan view and including the same material as the first common electrode, wherein the first electrode pattern is spaced apart from the first common electrode.

In an embodiment, the one surface of the second bank layer may overlap the protruding tip of the bank structure and may include a first portion in contact with the first electrode pattern; and a second portion in contact with the first common electrode, where the first portion and the second portion may be spaced apart from each other.

In an embodiment, the one surface of the second bank layer may further include a third portion disposed between the first portion and the second portion, and the third portion may be in contact with the first encapsulation layer.

In an embodiment, the first encapsulation layer may be in contact with and cover both the first common electrode and the first electrode pattern and may have a compressive stress.

In an embodiment, an absolute value of the compressive stress of the first encapsulation layer may range from about 100 megapascals (MPa) to about 300 Mpa.

In an embodiment, a display device may further include: a second pixel electrode spaced apart from the first pixel electrode and having the pixel defining layer interposed therebetween; a second light emitting layer disposed on the second pixel electrode; and a second common electrode disposed on the second light emitting layer, where the first encapsulation layer further includes: a first inorganic layer covering the first common electrode; and a second inorganic layer covering the second common electrode, and the first inorganic layer and the second inorganic layer may be spaced apart from each other.

In an embodiment, a display device may further include a second encapsulation layer disposed on the first encapsulation layer, where the second encapsulation layer may be in contact with the second bank layer of the bank structure at a portion in which the first inorganic layer and the second inorganic layer are spaced apart from each other.

An embodiment of a display device includes: a substrate; a first pixel electrode disposed on the substrate; a pixel defining layer disposed on the substrate and defining a first opening overlapping the first pixel electrode in a plan view; a bank structure disposed on the pixel defining layer and defining a second opening overlapping the first opening in the plan view; a first light emitting layer disposed on the first pixel electrode and in the first opening; a first common electrode disposed on the first light emitting layer and in contact with the bank structure in a region overlapping the second opening in the plan view; a first electrode pattern disposed to surround the first opening, disposed on the bank structure and spaced apart from the first common electrode; and an encapsulation layer disposed on the first common electrode and the first electrode pattern, where the bank structure comprises: a first bank layer disposed on the pixel defining layer and including a conductive material; and a second bank layer disposed on the first bank layer and including a tip protruding toward the first opening more than a side surface of the first bank layer, and the first electrode pattern includes a first surface covering a side surface of the second bank layer in the region overlapping the second opening and a second surface covering a bottom surface of the second bank layer facing the first bank layer.

In an embodiment, a display device may further comprise a first organic pattern disposed between the second bank layer and the first electrode pattern, wherein the first organic pattern includes a third surface disposed between the side surface of the second bank layer and the first surface of the first electrode pattern in the region overlapping the second opening in the plan view.

In an embodiment, the first organic pattern may be not in contact with the bottom surface of the second bank layer facing the first bank layer.

In an embodiment, the first common electrode may extend to the bottom surface where the first bank layer and the second bank layer come into contact, and wherein the first common electrode is in contact with the bottom surface of the second bank layer facing the first bank layer.

In an embodiment, the encapsulation layer may include compressive stress and closely adhere to and cover the first common electrode and the first electrode pattern.

In an embodiment, the encapsulation layer may include silicon nitride (SiNx), and an absolute value of the compressive stress of the encapsulation layer may range from about 100 MPa to about 300 MPa.

An embodiment of a display device includes a substrate; a first pixel electrode disposed on the substrate; a pixel defining layer disposed on the substrate and defining a first opening overlapping the first pixel electrode in a plan view; a bank structure disposed on the pixel defining layer and defining a second opening overlapping the first opening in the plan view; a first light emitting layer disposed on the first pixel electrode and in the first opening; a first common electrode disposed on the first light emitting layer and in contact with the bank structure in a region overlapping the second opening in the plan view; and an encapsulation layer disposed on the first common electrode and the bank structure, where the bank structure comprises: a first bank layer disposed on the pixel defining layer and includes a conductive material layer; and a second bank layer disposed on the first bank layer and including a tip protruding toward the first opening more than a side surface of the first bank layer, and the encapsulation layer has a compressive stress and closely adheres to and covers the first common electrode and the protruding tip of the bank structure.

In accordance with the display device according to embodiments, defects due to external moisture permeation may be reduced and display quality may be effectively improved by providing an encapsulation layer with improved adhesion to the common electrode.

In accordance with the display device according to embodiments, defects of the display device due to film lifting between a bank structure and an encapsulation layer may be reduced and the display quality may be effectively improved.

It should be noted that the effects of the present disclosure are not limited to those described above, and other effects of the present disclosure will be apparent from the following description.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic perspective view of the electronic device 1 according to an embodiment;

FIG. 2 is a perspective view of the display device 10 included in the electronic device 1 according to the embodiment;

FIG. 3 is a cross-sectional view of the display device 10 of FIG. 2 as viewed from the side;

FIG. 4 is a plan view of a display layer of a display device according to an embodiment;

FIG. 5 is a plan view illustrating the arrangement of emission areas in a first display area of the display device according to the embodiment;

FIG. 6 is a cross-sectional view taken along line X1-X1′ of a display device of FIG. 5;

FIG. 7 is an enlarged cross-sectional view of the first emission area EA1 of FIG. 6;

FIG. 8 is an enlarged cross-sectional view of area ‘A’ of FIG. 7;

FIG. 9 is an enlarged cross-sectional view of area ‘B’ of FIG. 7;

FIG. 10 is a schematic view showing tensile stress and compressive stress of a thin film;

FIG. 11 is a cross-sectional view showing a compressive stress direction of an encapsulation layer in a first emission area of FIG. 6; and

FIG. 12 is an enlarged cross-sectional view of area ‘C’ of FIG. 6.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The same reference numbers indicate the same components throughout the specification. In the attached figures, the thickness of layers and regions is exaggerated for clarity.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the disclosure will be described with reference to the accompanying drawings.

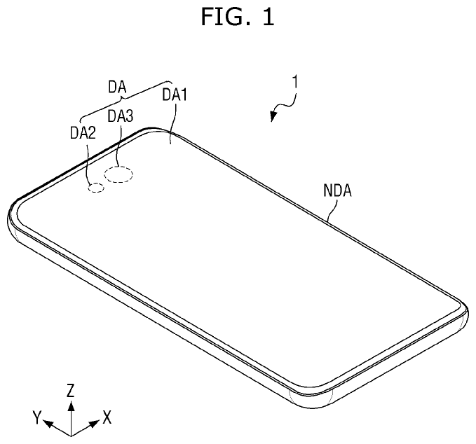

FIG. 1 is a schematic perspective view of the electronic device 1 according to an embodiment.

Referring to FIG. 1, an electronic device 1 displays moving images or still images. The electronic device 1 may refer to any electronic device that provides a display screen. Examples of the electronic device 1 may include a television, a notebook computer, a monitor, a billboard, an Internet of things (“IoT”) device, a mobile phone, a smartphone, a tablet personal computer (“PC”), an electronic watch, a smart watch, a watch phone, a head-mounted display, a mobile communication terminal, an electronic notebook, an electronic book, a portable multimedia player (“PMP”), a navigation device, a game console, a digital camera and a camcorder, all of which provide a display screen.

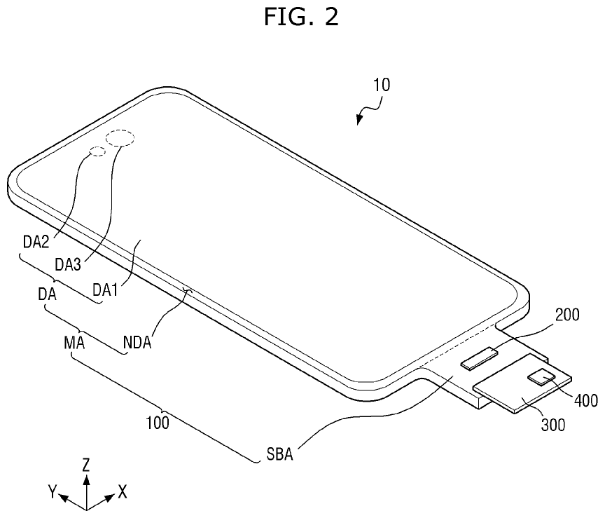

The electronic device 1 may include a display device 10 (see FIG. 2) that provides a display screen. Examples of the display device 10 may include an inorganic light emitting diode display device, an organic light emitting display device, a quantum dot light emitting display device, a plasma display panel, and a field emission display device, A case where an organic light emitting diode display device is applied as an example of the display device 10 will be described below, but the present disclosure is not limited to this case, and other display devices can also be applied as long as the same technical spirit is applicable.

The shape of the electronic device 1 can be variously modified. For example, the electronic device 1 may have various shapes such as a horizontally long rectangle, a vertically long rectangle, a square, a quadrilateral with rounded corners (vertices), other polygons, and a circle. The shape of a display area DA of the electronic device 1 may also be similar to the overall shape of the electronic device 1. In FIG. 1, the electronic device 1 is shaped like a rectangle that is long in a second direction Y.

The electronic device 1 may include the display area DA and a non-display area NDA. The display area DA may be an area where a screen can be displayed, and the non-display area NDA may be an area where no screen is displayed. The display area DA may also be referred to as an active area, and the non-display area NDA may also be referred to as an inactive area. The display area DA may generally occupy a center of the electronic device 1.

The display area DA may include a first display area DA1, a second display area DA2, and a third display area DA3. The second display area DA2 and the third display area DA3 may be areas where components for adding various functions to the electronic device 1 are disposed. The second display area DA2 and the third display area DA3 may be component areas.

FIG. 2 is a perspective view of the display device 10 included in the electronic device 1 in a state that a sub-area SBA is not bent according to the embodiment.

Referring to FIG. 2, the electronic device 1 according to the embodiment may include the display device 10. The display device 10 may provide a screen that is displayed by the electronic device 1. The display device 10 may have a planar shape similar to a shape of the electronic device 1. For example, the display device 10 may be shaped like a rectangle having short sides in a first direction X and long sides in the second direction Y. Each corner where a short side extending in the first direction X meets a long side extending in the second direction Y may be rounded with a predetermined curvature. However, the present disclosure is not limited thereto, and each corner may also be right-angled in another embodiment. The planar shape of the display device 10 is not limited to a quadrilateral shape but may also be another polygonal shape, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and anon-display area NDA disposed around the display area DA. The display area DA may include a first display area DAT, a second display area DA2, and a third display area DA3. The display area DA may emit light from a plurality of emission areas or a plurality of opening areas. For example, the display panel 100 may include pixel circuits including switching elements, a pixel defining layer defining the emission areas or the opening areas, and self-light emitting elements.

For example, the self-light emitting elements may include at least one of, but not limited to, an organic light emitting diode including an organic light emitting layer, a quantum dot light emitting diode including a quantum dot light emitting layer, an inorganic light emitting diode including an inorganic semiconductor, and a micro-light emitting diode.

The non-display area NDA may be an area outside the display area DA. The non-display area NDA may be defined as an edge area of the main area MA of the display panel 100. The non-display area NDA may include a gate driver (not illustrated) supplying gate signals to gate lines and fan-out lines (not illustrated) connecting the display driver 200 and the display area DA.

The sub-area SBA may be an area extending from a side of the main area MA. The sub-area SBA may include a flexible material that can be bent, folded, rolled, etc. For example, when the sub-area SBA is bent, it may be overlapped by the main area MA in a thickness direction (a third direction Z). The sub-area SBA may include the display driver 200 and a pad unit connected to the circuit board 300. In an embodiment, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (“COG”) method, a chip on plastic (“COP”) method, or an ultrasonic bonding method. For example, the display driver 200 may be disposed in the sub-area SBA and may be overlapped by the main area MA in the thickness direction (i.e., third direction Z) by the bending of the sub-area SBA. For another example, the display driver 200 may be mounted on the circuit board 300.

The circuit board 300 may be attached onto the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film such as a chip on film.

The touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and sense a change in capacitance between the touch electrodes. For example, the touch driving signal may be a pulse signal having a predetermined frequency. The touch driver 400 may calculate whether an input has been made and coordinates of the input based on a change in capacitance between the touch electrodes. The touch driver 400 may be formed as an integrated circuit.

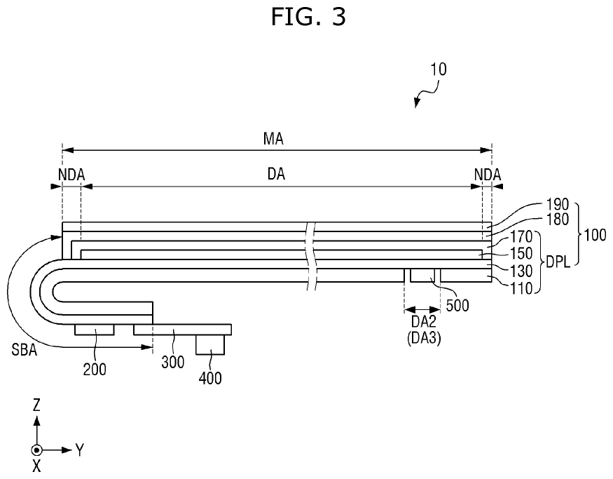

FIG. 3 is a cross-sectional view of the display device 10 of FIG. 2 in a state that the sub-area SBA is bent as viewed from the side.

Referring to FIG. 3, the display panel 100 may include a display layer DPL, a touch sensing layer 180, and a color filter layer 190. In addition, the display layer DPL may include a substrate 110, a thin-film transistor layer 130, a light emitting element layer 150, and a thin-film encapsulation layer 170.

The substrate 110 may be a base substrate or a base member. The substrate 110 may be a flexible substrate that can be bent, folded, rolled, etc. For example, the substrate 110 may include polymer resin such as polyimide PI. However, the present disclosure is not limited thereto. For another example, the substrate 110 may include a glass material or a metal material.

The thin-film transistor layer 130 may be disposed on the substrate 110. The thin-film transistor layer 130 may include a plurality of thin-film transistors constituting pixel circuits of pixels. The thin-film transistor layer 130 may further include gate lines, data lines, power lines, gate control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. For example, when the gate driver is formed on a side of the non-display area NDA of the display panel 100, it may include thin-film transistors.

The thin-film transistor layer 130 may be disposed in the display area DA, the non-display area NDA, and the sub-area SBA. The thin-film transistors of the pixels, the gate lines, the data lines, and the power lines of the thin-film transistor layer 130 may be disposed in the display area DA. The gate control lines and the fan-out lines of the thin-film transistor layer 130 may be disposed in the non-display area NDA. The lead lines of the thin-film transistor layer 130 may be disposed in the sub-area SBA.

The light emitting element layer 150 may be disposed on the thin-film transistor layer 130. The light emitting element layer 150 may include a plurality of light emitting elements, each including a first electrode, a second electrode and a light emitting layer to emit light, and a pixel defining layer defining the pixels. The light emitting elements of the light emitting element layer 150 may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through a thin-film transistor of the thin-film transistor layer 130 and the second electrode receives a cathode voltage, holes and electrons may move to the organic light emitting layer through the hole transporting layer and the electron transporting layer, respectively, and may be combined with each other in the organic light emitting layer to emit light.

In an embodiment, the light emitting elements may include a quantum dot light emitting diode including a quantum dot light emitting layer, an inorganic light emitting diode including an inorganic semiconductor, or a micro-light emitting diode.

The thin-film encapsulation layer 170 may cover upper and side surfaces of the light emitting element layer 150 and may protect the light emitting element layer 150. The thin-film encapsulation layer 170 may include at least one inorganic layer and at least one organic layer to encapsulate the light emitting element layer 150.

The touch sensing layer 180 may be disposed on the thin-film encapsulation layer 170. The touch sensing layer 180 may include a plurality of touch electrodes for sensing a user's touch in a capacitive manner and touch lines connecting the touch electrodes and the touch driver 400. For example, the touch sensing layer 180 may sense a user's touch in a mutual capacitance manner or a self-capacitance manner.

In an embodiment, the touch sensing layer 180 may be disposed on a separate substrate disposed on the display layer DPL. In this case, the substrate that supports the touch sensing layer 180 may be a base member that encapsulates the display layer DPL.

The touch electrodes of the touch sensing layer 180 may be disposed in a touch sensor area overlapping the display area DA. The touch lines of the touch sensing layer 180 may be disposed in a touch peripheral area overlapping the non-display area NDA.

In some embodiments, the display device 10 may further include an optical device 500. The optical device 500 may be disposed in the second display area DA2 or the third display area DA3. The optical device 500 may emit or receive light in an infrared, ultraviolet, or visible light band. For example, the optical device 500 may be an optical sensor that senses light incident on the display device 10, such as a proximity sensor, an illuminance sensor, a camera sensor or an image sensor.

The color filter layer 190 may be disposed on the thin-film encapsulation layer 170 to overlap emission areas in a plan view. The color filter layer 190 may include a plurality of color filters corresponding to the emission areas, respectively. Each of the color filters may selectively transmit light of a specific wavelength and block or absorb light of other wavelengths. The color filter layer 190 may absorb a portion of light introduced from the outside of the display device 10 to reduce reflected light due to the external light. Therefore, the color filter layer 190 can prevent color distortion due to reflection of the external light.

Since the color filter layer 190 is directly disposed on the thin-film encapsulation layer 170, the display device 10 may not require a separate substrate for the color filter layer 190. Therefore, a thickness of the display device 10 may be relatively small.

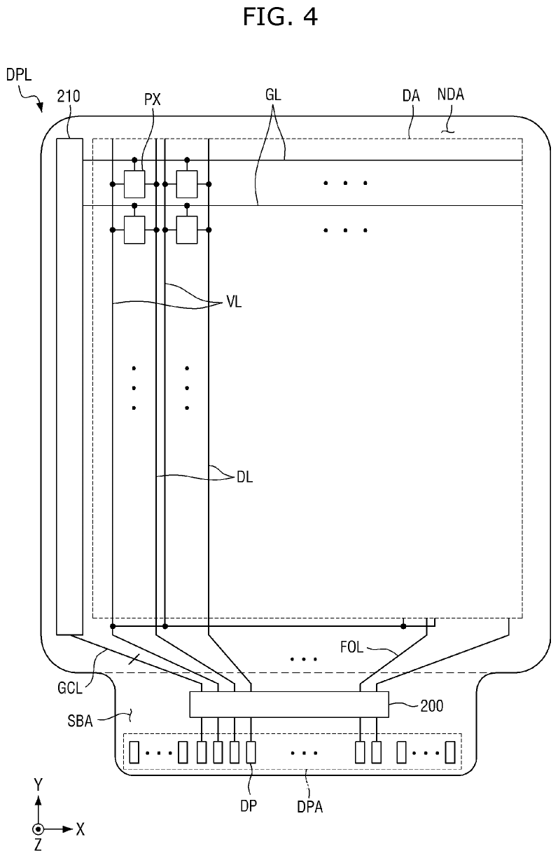

FIG. 4 is a plan view of a display layer DPL of a display device 10 in a state that the sub-area SBA is not bent according to an embodiment. As used herein, the “plan view” is a view in a third direction Z (i.e., thickness direction of the bank layer or the substrate).

Referring to FIG. 4, the display layer DPL may include a display area DA and a non-display area NDA.

The display area DA may be disposed in a center of a display panel 100. In the display area DA, a plurality of pixels PX, a plurality of gate lines GL, a plurality of data lines DL, and a plurality of power lines VL may be disposed. Each of the pixels PX may be defined as a minimum unit that emits light.

The gate lines GL may supply gate signals received from a gate driver 210 to the pixels PX. The gate lines GL may extend in the first direction X and may be spaced apart from each other in the second direction Y intersecting the first direction X.

The data lines DL may supply data voltages received from a display driver 200 to the pixels PX. The data lines DL may extend in the second direction Y and may be spaced apart from each other in the first direction X.

The power lines VL may supply a power supply voltage received from the display driver 200 to the pixels PX. Here, the power supply voltage may be at least one of a driving voltage, an initialization voltage, a reference voltage, and a low-potential voltage. The power lines VL may extend in the second direction Y and may be spaced apart from each other in the first direction X.

The non-display area NDA may surround the display area DA. In the non-display area NDA, the gate driver 210, fan-out lines FOL, and gate control lines GCL may be disposed. The gate driver 210 may generate a plurality of gate signals based on a gate control signal and sequentially supply the gate signals to the gate lines CL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

A sub-area SBA may include the display driver 200 and a pad area DPA.

The display driver 200 may output signals and voltages for driving the display panel 100 to the fan-out lines FOL. The display driver 200 may supply data voltages to the data lines DL through the fan-out lines FOL. The data voltages may be supplied to the pixels PX and may control luminances of the pixels PX. The display driver 200 may supply a gate control signal to the gate driver 210 through the gate control lines GCL.

The pad area DPA may be disposed at an edge of the sub-area SBA. The pad area DPA may be electrically connected to a circuit board 300 using an anisotropic conductive film or a material such as self-assembly anisotropic conductive paste (“SAP”).

The pad area DPA may include a plurality of display pads DP. The display pads DP may be connected to a graphics system through the circuit board 300. The display pads DP may be connected to the circuit board 300 to receive digital video data and may supply the digital video data to the display driver 200.

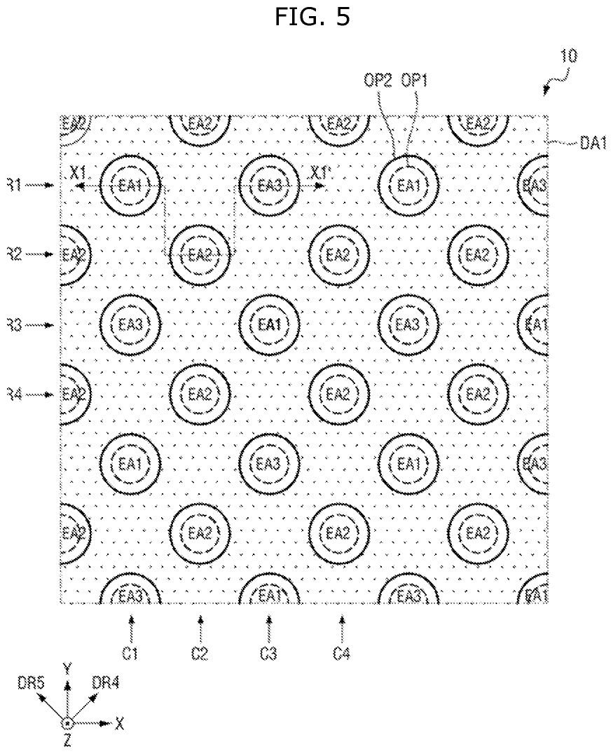

FIG. 5 is a plan view illustrating the arrangement of emission areas in a first display area of the display device according to the embodiment.

Referring to FIG. 5, the display device 10 may include a plurality of emission areas EA1 through EA3 disposed in the display area DA. The display area illustrated in FIG. 5 may be the first display area DA1, and the emission areas EA1 through EA3 may be disposed in the first display area DA1. However, the emission areas EA1 through EA3 may also be disposed in a second display area DA2 and a third display area DA3 of the display area DA.

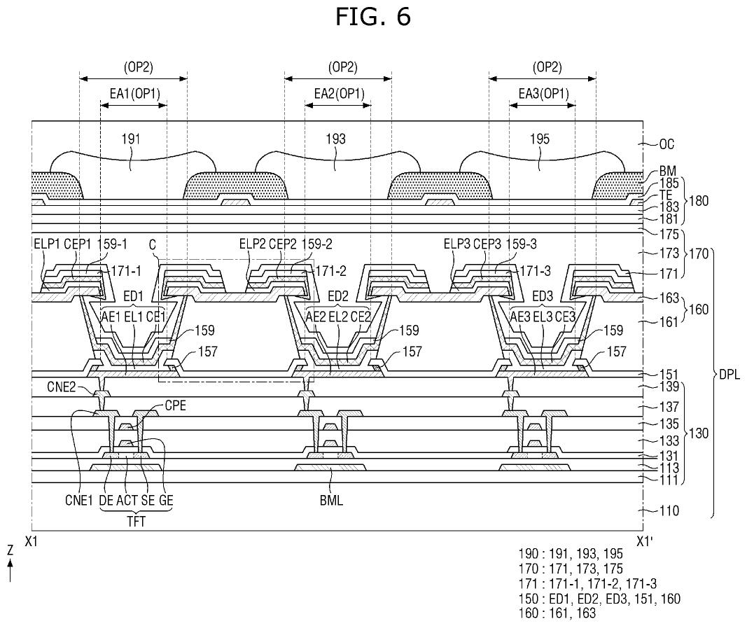

The emission areas EA1 through EA3 may include first emission areas EA1, second emission areas EA2, and third emission areas EA3 that emit light of different colors. Each of the first through third emission areas EA1 through EA3 may emit red, green or blue light, and the color of light emitted from each of the emission areas EA1 through EA3 may vary according to the type of light emitting element ED1, ED2 or ED3 (see FIG. 6) disposed in a light emitting element layer 150 which will be described later. In an embodiment, the first emission areas EA1 may emit red first light, the second emission areas EA2 may emit green second light, and the third emission areas EA3 may emit blue third light. However, the present disclosure is not limited thereto.

The emission areas EA1 through EA3 may be arranged in a PenTile™ type, for example, a diamond PenTile™ type. For example, the first emission areas EA1 and the third emission areas EA3 may be spaced apart from each other in the first direction X and may be alternately disposed in the first direction X and the second direction Y. In the arrangement of the emission areas EA1 through EA3, the first emission areas EA1 and the third emission areas EA3 may be alternately disposed in the first direction X in a first row R1 and a third row R3. The first emission areas EA1 and the third emission areas EA3 may be alternately disposed in the second direction Y in a first column C1 and a third column C3.

Each of the second emission areas EA2 may be spaced apart from other adjacent second emission areas EA2 in the first direction X and the second direction Y and may be spaced apart from adjacent first and third emission areas EA1 and EA3 in a fourth direction DR4 or a fifth direction DR5. The second emission areas EA2 may be repeatedly disposed along the first direction X and the second direction Y. The second emission areas EA2 and the first emission areas EA1 or the second emission areas EA2 and the third emission areas EA3 may be alternately disposed along the fourth direction DR4 or the fifth direction DR5. In the arrangement of the emission areas EA1 through EA3, the second emission areas EA2 may be repeatedly disposed in the first direction X in a second row R2 and a fourth row R4 and may be repeatedly disposed in the second direction Y in a second column C2 and a fourth column C4.

The first through third emission areas EA1 through EA3 may be defined by a plurality of first and second openings OP1 and OP2, respectively, formed by an inorganic pixel defining layer 151 (see FIG. 6) of the light emitting element layer 150 and a bank structure 160 (see FIG. 6) which will be described later.

FIG. 6 is a cross-sectional view taken along line X1-X1′ of a display device of FIG. 5.

FIG. 6 is a partial cross-sectional view of the display device 10, illustrating cross-sections of a substrate 110, a thin-film transistor layer 130, the light emitting element layer 150, a thin-film encapsulation layer 170, a touch sensing layer 180, and a color filter layer 190.

Referring to FIG. 6, the display layer DPL may include the substrate 110, the thin-film transistor layer 130, the light emitting element layer 150, and the thin-film encapsulation layer 170.

Since the substrate 110 is described in descriptions of FIG. 3, the redundant description will be omitted.

The thin-film transistor layer 130 may be positioned on the substrate 110. The thin-film transistor layer 130 may include a first buffer layer 111, bottom metal layers BML, a second buffer layer 113, thin-film transistors TFT, a gate insulating layer 131, a first interlayer insulating layer 133, capacitor electrodes CPE, a second interlayer insulating layer 135, first connection electrodes CNE1, a first passivation layer 137, second connection electrodes CNE2, and a second passivation layer 139.

The first buffer layer 111 may be disposed on the substrate 110. The first buffer layer 111 may include an inorganic layer that can prevent penetration of air or moisture. For example, the first buffer layer 11I may include a plurality of inorganic layers stacked alternately.

The bottom metal layers BML may be disposed on the first buffer layer 111. For example, each of the bottom metal layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer 113 may cover the first buffer layer 111 and the bottom metal layers BML. The second buffer layer 113 may include an inorganic layer that can prevent penetration of air or moisture. For example, the second buffer layer 113 may include a plurality of inorganic layers stacked alternately.

The thin-film transistors TFT may be disposed on the second buffer layer 113 and may constitute respective pixel circuits of a plurality of pixels. For example, each of the thin-film transistors TFT may be a driving transistor or a switching transistor of a pixel circuit. Each of the thin-film transistors TFT may include a semiconductor layer ACT, a source electrode SE, a drain electrode DE, and a gate electrode GE.

The semiconductor layer ACT may be disposed on the second buffer layer 113. The semiconductor layer ACT may overlap a bottom metal layer BML and the gate electrode GE in the thickness direction and may be insulated from the gate electrode GE by the gate insulating layer 131. In portions of the semiconductor layer ACT, the material of the semiconductor layer ACT may be made conductive to form the source electrode SE and the drain electrode DE.

The gate electrode GE ray be disposed on the gate insulating layer 131. The gate electrode GE nay overlap the semiconductor layer ACT with the gate insulating layer 131 interposed between them in a plan view.

The gate insulating layer 131 may be disposed on the semiconductor layers ACT. For example, the gate insulating layer 131 may cover the semiconductor layers ACT and the second buffer layer 113 and may insulate the semiconductor layers ACT from the gate electrodes GE. The gate insulating layer 131 may include contact holes through which the first connection electrodes CNE1 pass.

The first interlayer insulating layer 133 may cover the gate electrodes GE and the gate insulating layer 131. The first interlayer insulating layer 133 may include contact holes through which the first connection electrodes CNE1 pass. The contact holes of the first interlayer insulating layer 133 may be connected to the contact holes of the gate insulating layer 131 and contact holes of the second interlayer insulating layer 135.

The capacitor electrodes CPE may be disposed on the first interlayer insulating layer 133. The capacitor electrodes CPE may overlap the gate electrodes GE in the thickness direction. The capacitor electrodes CPE and the gate electrodes GE may form capacitances.

The second interlayer insulating layer 135 may cover the capacitor electrodes CPE and the first interlayer insulating layer 133. The second interlayer insulating layer 135 may include the contact holes through which the first connection electrodes CNE1 pass. The contact holes of the second interlayer insulating layer 135 may be connected to the contact holes of the first interlayer insulating layer 133 and the contact holes of the gate insulating layer 131.

The first connection electrodes CNE1 may be disposed on the second interlayer insulating layer 135. The first connection electrodes CNE1 may electrically connect the drain electrodes DE of the thin-film transistors TFT to the second connection electrodes CNE2. The first connection electrodes CNE1 may be inserted into the contact holes formed in the second interlayer insulating layer 135, the first interlayer insulating layer 133 and the gate insulating layer 131 to contact the drain electrodes DE of the thin-film transistors TFT.

The first passivation layer 137 may cover the first connection electrodes CNE1 and the second interlayer insulating layer 135. The first passivation layer 137 may protect the thin-film transistors TFT. The first passivation layer 137 may include contact holes through which the second connection electrodes CNE2 pass.

The second connection electrodes CNE2 may be disposed on the first passivation layer 137. The second connection electrodes CNE2 may electrically connect the first connection electrodes CNE1 to pixel electrodes AE1 through AE3 of light emitting elements ED1 through ED3. The second connection electrodes CNE2 may be inserted into the contact holes formed in the first passivation layer 137 to contact the first connection electrodes CNE1.

The second passivation layer 139 may cover the second connection electrodes CNE2 and the first passivation layer 137. The second passivation layer 139 may include contact holes through which the pixel electrodes AE1 through AE3 of the light emitting elements ED1 through ED3 pass.

The light emitting element layer 150 may be disposed on the thin-film transistor layer 130. The light emitting element layer 150 may include the light emitting elements ED1 through ED3, the inorganic pixel defining layer 151, and the bank structure 160. Each of the light emitting elements ED1 through ED3 may include the pixel electrode AE1, AE2 or AE3, a light emitting layer EL1, EL2 or EL3, and a common electrode CE1, CE2 or CE3.

The display device 10 may include a plurality of emission areas EA1, EA2 and EA3 disposed in the display area DA. The first through third emission areas EA1 through EA3 may be defined by the first opening OP1 defined by the inorganic pixel defining layer 151 of the light emitting element layer 150 and the second openings OP2 defined by the bank structure 160.

In some embodiments, the first through third emission areas EA1 through EA3 may have the same area or size. For example, in the display device 10, the second openings OP2 of the bank structure 160 may have the same diameter, and the first through third emission areas EA1 through EA3 may have the same area. However, the present disclosure is not limited thereto.

In some embodiments, in the display device 10, the first through third emission areas EA1 through EA3 may also have different areas or sizes. For example, the area of each second emission area EA2 may be larger than the area of each first emission area EA1 and the area of each third emission area EA3, and the area of each third emission area EA3 may be larger than the area of each first emission area EA1. The intensity of light emitted from each of the emission areas EA1 through EA3 may vary according to the area of the emission area EA1, EA2 or EA3, and the color of a screen displayed on the display device 10 or the electronic device 1 may be controlled by adjusting the area of each of the emission areas EA1 through EA3. That is, the areas of the emission areas EA1 through EA3 may be freely adjusted according to the color of the screen required by the display device 10 and the electronic device 1.

In the display device 10, one first emission area EA1, one second emission area EA2, and one third emission area EA3 adjacent to each other may form one pixel group. One pixel group may include the emission areas EA1 through EA3 emitting light of different colors to express a white gray level. However, the present disclosure is not limited thereto, and the combination of the emission areas EA1 through EA3 constituting one pixel group can be variously modified according to the arrangement of the emission areas EA1 through EA3 and the colors of light emitted from the emission areas EA1 through EA3.

The display device 10 may include a plurality of light emitting elements ED1 through ED3 disposed in different emission areas EA1 through EA3. The light emitting elements ED1 through ED3 may include a first light emitting element ED1 disposed in the first emission area EA1, a second light emitting element ED2 disposed in the second emission area EA2, and a third light emitting element ED3 disposed in the third emission area EA3. The light emitting elements ED1 through ED3 may include the pixel electrodes AE1 through AE3, the light emitting layers EL1 through EL3, and the common electrodes CET through CE3, respectively. The light emitting elements ED1 through ED3 disposed in different emission areas EA1 through EA3 may emit light of different colors depending on the materials of the light emitting layers EL1 through EL3. For example, the first light emitting element ED1 disposed in the first emission area EA1 may emit red light of a first color, the second light emitting element ED2 disposed in the second emission area EA2 may emit green light of a second color, and the third light emitting element ED3 disposed in the third emission area EA3 may emit blue light of a third color. The first through third emission areas EA1 through EA3 constituting one pixel may include the light emitting elements ED1 through ED3 emitting light of different colors to express a white gray level.

The pixel electrodes AE1 through AE3 may be disposed on the second passivation layer 139. The pixel electrodes AE1 through AE3 may be electrically connected to the drain electrodes DE of the thin-film transistors TFT through the first and second connection electrodes CNE1 and CNE2.

The pixel electrodes AE1 through AE3 may be disposed in the emission areas EA1 through EA3, respectively. The pixel electrodes AE1 through AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other on the second passivation layer 139. The pixel electrodes AE1 through AE3 may be disposed in different emission areas EA1 through EA3 to form the light emitting elements ED1 through ED3 emitting light of different colors, respectively.

In an embodiment, the pixel electrodes AE1 through AE3 may have a stacked structure of a material layer having a high work function such as indium tin oxide (“ITO”), indium zinc oxide (“IZO”), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a mixture thereof. The material layer having a high work function may be disposed on the reflective material layer so that it is located close to the light emitting layers EL1 through EL3. For example, the pixel electrodes AE1 through AE3 may have, but not limited to, a multilayer structure of ITO/Mg, ITO/MgF, ITO/Ag, or ITO/Ag/ITO.

The display device 10 may include the inorganic pixel defining layer 151 disposed on the second passivation layer 139 and the pixel electrodes AE1 through AE3. The inorganic pixel defining layer 151 may define a plurality of first openings OP1 forming emission areas EA1 through EA3. The inorganic pixel defining layer 151 may be entirely disposed on the second passivation layer 139 but may partially expose the upper surfaces of the pixel electrodes AE1 through AE3 while partially overlapping the pixel electrodes AE1 through AE3 in a plan view. For example, the inorganic pixel defining layer 151 may expose the pixel electrodes AE1 through AE3 in each portion overlapping the first openings OP1 in a plan view, and the light emitting layers EL1 through EL3 may be directly disposed on the pixel electrodes AE1 through AE3, respectively.

The inorganic pixel defining layer 151 may include an inorganic insulating material. For example, the inorganic pixel defining layer 151 may include aluminum oxide, titanium oxide, tantalum oxide, hafnium oxide, zinc oxide, silicon oxide, silicon nitride, or silicon oxynitride.

A bank structure 160 may be positioned on the inorganic pixel defining layer 151. The bank structure 160 may define a plurality of second openings OP2 forming the emission areas EA1 through EA3, and the light emitting elements EDT through ED3 of the display device 10 may be disposed to overlap the second opening OP2 of the bank structure 160 in a plan view. The bank structure 160 may include a first bank layer 161 and a second bank layer 163 serving different functions by including different metal materials and structures. The bank structure 160 will be described in more detail later.

The light emitting layers EL1 through EL3 may be disposed on the pixel electrodes AE1 through AE3. The light emitting layers EL1 through EL3 may be organic light emitting layers made of an organic material and may be formed on the pixel electrodes AE1 through AE3 through a deposition process. When the thin-film transistors TFT apply a predetermined voltage to the pixel electrodes AE1 through AE3 of the light emitting elements ED1 through ED3 and when the common electrodes CET through CE3 of the light emitting elements ED1 through ED3 receive a common voltage or a cathode voltage, holes and electrons may move to the light emitting layers EL1 through EL3 through a hole transporting layer and an electron transporting layer, respectively. Then, the holes and electrons may be combined with each other in the light emitting layers EL1 through EL3 to emit light.

The light emitting layers EL1 through EL3 may include a first light emitting layer ELT, a second light emitting layer EL2, and a third light emitting layer EL3 disposed in different emission areas EA1 through EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. The first through third light emitting layers EL1 through EL3 may be light emitting layers of the first through third light emitting elements ED1 through ED3, respectively. The first light emitting layer EL1 may be alight emitting layer emitting red light of the first color, the second light emitting layer EL2 may be a light emitting layer emitting green light of the second color, and the third light emitting layer EL3 may be a light emitting layer emitting blue light of the third color.

In some embodiments, portions of the light emitting layers EL1 through EL3 of the light emitting elements ED1 through ED3 may be disposed between the pixel electrodes AE1 through AE3 and the inorganic pixel defining layer 151. The inorganic pixel defining layer 151 may be disposed on the pixel electrodes AE1 through AE3, but may be spaced apart from upper surfaces of the pixel electrodes AE1 through AE3. In the deposition process of the light emitting layers EL1 through EL3, the materials of the light emitting layers EL1 through EL3 may be deposited in a direction inclined to an upper surface of the substrate 110 rather than in a direction perpendicular to the upper surface of the substrate 110. Accordingly, the light emitting layers EL1 through EL3 may be formed on the upper surfaces of the pixel electrodes AE1 through AE3 exposed through the second openings OP2 of the bank structure 160 and may fill spaces between the pixel electrodes AE1 through AE3 and the inorganic pixel defining layer 151. The deposition process of the light emitting layers EL1 through EL3 will be described in detail later.

In the manufacturing process of the display device 10, a temporary protective layer may be disposed between the inorganic pixel defining layer 151 and the pixel electrodes AE1 through AE3, then partially removed later. The light emitting layers EL1 through EL3 may be disposed in areas where the temporary protective layer is partially removed, and a lower surface of the inorganic pixel defining layer 151 may be spaced apart from the pixel electrodes AE1 through AE3. A portion of the temporary protective layer that is not removed may remain as a residual pattern 157 in an area between the inorganic pixel defining layer 151 and the pixel electrodes AE1 through AE3. Accordingly, an area between the inorganic pixel defining layer 151 and each of the pixel electrodes AE1 through AE3 may be partially filled with the residual pattern 157 and the light emitting layers EL1 through EL3.

The common electrodes CE1 through CE3 may be disposed on the light emitting layers EL1 through EL3. The common electrodes CE1 through CE3 may include a transparent conductive material to allow light generated by the light emitting layers EL1 through EL3 to pass therethrough. The common electrodes CE1 through CE3 may receive a common voltage or a low-potential voltage. When the pixel electrodes AE1 through AE3 receive voltages corresponding to data voltages and the common electrodes CE1 through CE3 receive a low-potential voltage, a potential difference may be formed between the pixel electrodes AE1 through AE3 and the common electrodes CE1 through CE3. Accordingly, the light emitting layers EL1 through EL3 may emit light.

In an embodiment, the common electrodes CE1 through CE3 may include a material layer having a small work function such as Li, Ca, LiF/Ca, LiF/Al, Al, Mg, Ag, Pt, Pd, Ni, Au Nd, Jr, Cr, BaF, Ba, or a compound or mixture thereof (e.g., a mixture of Ag and Mg). The common electrodes CE1 through CE3 may further include a transparent metal oxide layer disposed on the material layer having a small work function.

The common electrodes CET through CE3 may include a first common electrode CET, a second common electrode CE2, and a third common electrode CE3 disposed in different emission areas EA1 through EA3. The first common electrode CET may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3.

The common electrodes CET through CE3 disposed in the different emission areas EA1 through EA3 may not be directly connected, but may be electrically connected through the first bank layer 161 of the bank structure 160.

Capping layers 159 may be disposed on the common electrodes CET through CE3. The capping layers 159 may include an inorganic insulating material to cover the light emitting elements ED1 through ED3 and patterns disposed on the bank structure 160. The capping layers 159 may prevent the light emitting elements ED1 through ED3 from being damaged by external air and prevent the patterns disposed on the bank structure 160 from being peeled off during the fabrication process of the display device 10. In an embodiment, the capping layers 159 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), or silicon oxynitride (Si₂N₂O).

The thin-film encapsulation layer 170 may be disposed on the light emitting elements ED1 through ED3 and the bank structure 160 and may cover the light emitting elements ED1 through ED3 and the bank structure 160. The thin-film encapsulation layer 170 may include at least one inorganic layer to prevent oxygen or moisture from penetrating into the light emitting element layer 150. The thin-film encapsulation layer 170 may include at least one organic layer to protect the light emitting element layer 150 from foreign substances such as dust.

In an embodiment, the thin-film encapsulation layer 170 may include a first encapsulation layer 171, a second encapsulation layer 173, and a third encapsulation layer 175 stacked sequentially. The first encapsulation layer 171 and the third encapsulation layer 175 may be inorganic encapsulation layers, and the second encapsulation layer 173 disposed between them may be an organic encapsulation layer.

Each of the first encapsulation layer 171 and the third encapsulation layer 175 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may include a polymer-based material. Examples of the polymer-based material may include acrylic resin, epoxy resin, polyimide, and polyethylene. For example, the second encapsulation layer 173 may include acrylic resin such as polymethyl methacrylate or polyacrylic acid. The second encapsulation layer 173 may be formed by curing a monomer or applying a polymer.

The touch sensing layer 180 may be disposed on the thin-film encapsulation layer 170. The touch sensing layer 180 may include a touch buffer layer 181, a touch insulating layer 183, touch electrodes TE, and a touch protection layer 185.

The touch buffer layer 181 may be disposed on the thin-film encapsulation layer 170. The touch buffer layer 181 may have insulating and optical functions. The touch buffer layer 181 may include at least one inorganic layer. Optionally, the touch buffer layer 181 may be omitted.

Although not illustrated in the drawings, a connection electrode electrically connecting the touch electrodes may be disposed on the touch buffer layer 181.

The connection electrode may be a single layer of molybdenum (Mo), titanium (Ti, copper (Cu), aluminum (Al) or indium tin oxide (ITO) or may be a stacked structure (Ti/Al/Ti) of aluminum and titanium, a stacked structure (ITO/Al/ITO) of aluminum and indium tin oxide, an APC alloy, or a stacked structure (ITO/APC/TTO) of an APC alloy and indium tin oxide.

The touch insulating layer 183 may cover the touch buffer layer 181. The touch insulating layer 183 may have insulating and optical functions. For example, the touch insulating layer 183 may be an inorganic layer including at least one of a silicon nitride layer, a silicon oxynitride layer, a silicon oxide layer, a titanium oxide layer, and an aluminum oxide layer.

the touch electrodes TE may be disposed on the touch insulating layer 183. Each of the touch electrodes TE may not overlap the first through third emission areas EA1 through EA3 in a plan view. Each of the touch electrodes TE may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The touch protection layer 185 may cover the touch electrodes TE and the touch insulating layer 183. The touch protection layer 185 may have insulating and optical functions. The touch protection layer 185 may be made of at least one of the example materials of the touch insulating layer 183.

A light blocking layer BM may be disposed on the touch sensing layer 180. The light blocking layer BM may overlap the inorganic pixel defining layer 151 and the bank structure 160 in a plan view.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, and aniline black. However, the present disclosure is not limited thereto. The light blocking layer BM may prevent color mixing by preventing intrusion of visible light between the first through third emission areas EA1 through EA3, thereby improving a color gamut of the display device 10.

The color filter layer 190 may be disposed on the touch protection layer 185 and the light blocking layer BM to overlap the emission areas EA1 through EA3 in a plan view.

The color filter layer 190 may include a first color filter 191, a second color filter 193, and a third color filter 195 disposed to correspond to different emission areas EA1 through EA3, respectively. Each of the color filters 191, 193 and 195 may include a colorant such as a dye or pigment that absorbs light in wavelength bands other than light in a specific wavelength band and may be disposed to correspond to the color of light emitted from one of the emission areas EA1 through EA3. For example, the first color filter 191 may be a red color filter that overlaps the first emission area EA1 and transmits only red first light in a plan view. The second color filter 193 may be a green color filter that overlaps the second emission area EA2 in a plan view and transmits only green second light, and the third color filter 195 may be a blue color filter that overlaps the third emission area EA3 in a plan view and transmits only blue third light.

In FIG. 6, each of the color filters 191, 193 and 195 is spaced apart from other adjacent color filters 191, 193 and 195 on the light blocking layer BM. However, the present disclosure is not limited thereto. That is, each of the color filters 191, 193 and 195 may also partially overlap other adjacent color filters 191, 193 and 195 in a plan view. The different color filters 191, 193 and 195 may overlap each other on the light blocking layer BM in areas not overlapping the emission areas EA1 through EA3 in a plan view.

An overcoat layer OC may be disposed on the color filter layer 190 and the light blocking layer BM to planarize upper ends of the color filters 191, 193 and 195. The overcoat layer OC may be a colorless light-transmitting layer that does not have a color in a visible light band. For example, the overcoat layer OC may include a colorless light-transmitting organic material such as acrylic resin.

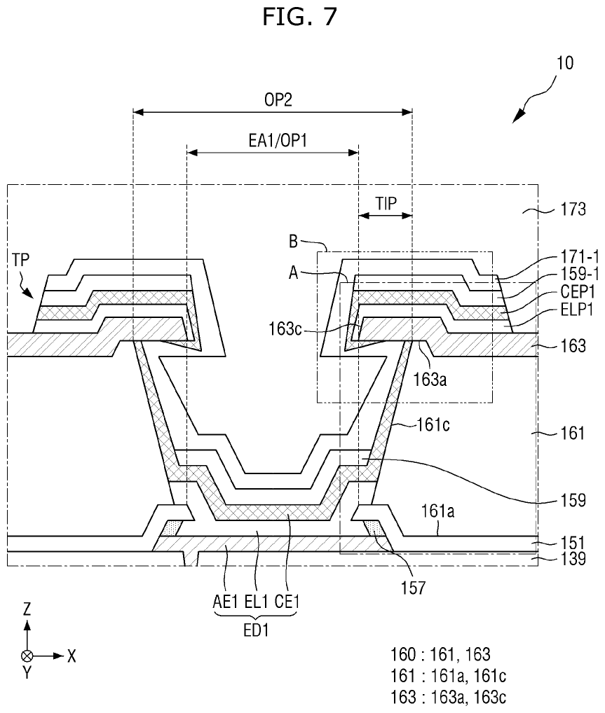

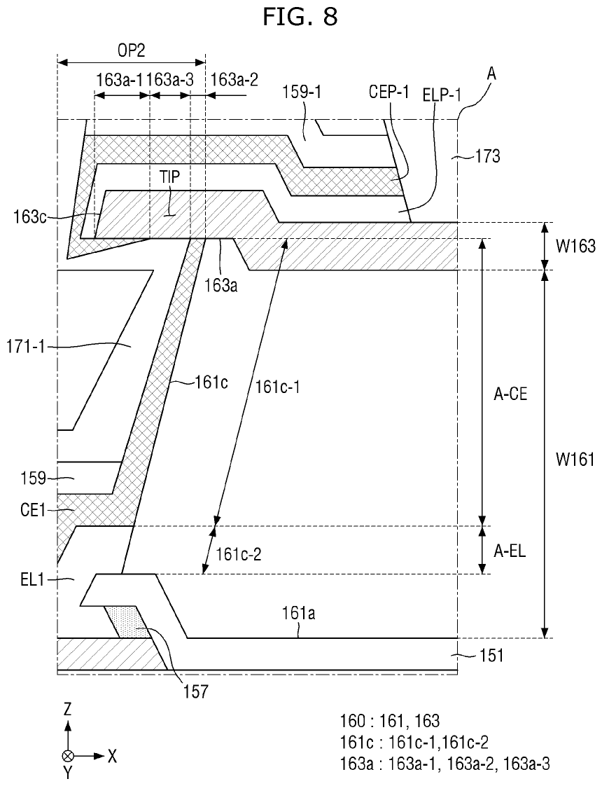

FIG. 7 is an enlarged cross-sectional view of the first emission area EA1 of FIG. 6. FIG. 8 is an enlarged cross-sectional view of area ‘A’ of FIG. 7.

Referring to FIGS. 7 and 8, the bank structure 160 may include a first bank layer 161 and a second bank layer 163 including different metal materials and structures from each other to play different roles. The first bank layer 161 may be positioned on the inorganic pixel defining layer 151, and the first bank layer 161 may include a first surface 161a in contact with the inorganic pixel defining layer 151 and a side surface 161c facing the first opening OP1.

The first bank layer 161 may include a metal having high electrical conductivity, and for example, the first bank layer 161 may include aluminum (Al). As described above, the common electrodes CE1 through CE3 of the display device 10 may not be directly connected to each other but may be electrically connected through the first bank layer 161 of the bank structure 160. Accordingly, as the contact area of the common electrodes CE1 through CE3 with the first bank layer 161 increases, the resistance of the display device 10 may decreases, and electrical characteristics may be stabilized. In some embodiments, a thickness W161 of the first bank layer 161 in the third direction Z may be greater than a thickness W163 of the second bank layer 163.

In some embodiments, the bank structure 160 may be formed by a deposition and etching process instead of a mask process, and the first bank layer 161 may be formed by a wet etch process. Accordingly, the side surface 161c of the first bank layer 161 may be recessed in the first direction X more than the inorganic pixel defining layer 151 to be positioned in the shape of an inclined surface inclined toward the first direction X in respect to the third direction (Z-axis direction).

The second bank layer 163 may be positioned on the first bank layer 161. The second bank layer 163 may include a first surface 163a in contact with the first bank layer 161 and a side surface 163c facing the first opening OP1. The thickness W163 of the second bank layer 163 in the third direction Z may be smaller than the thickness W161 of the first bank layer 161.

In some embodiments, the second bank layer 163 may include a material having a lower etch rate than the etch rate of the first bank layer 161. For example, the second bank layer 163 may include titanium (Ti). Like the first bank layer 161, the second bank layer 163 may be formed through a wet etch process, and as the second bank layer 163 includes a material relatively stable in the wet etch process compared to the first bank layer 161, the second bank layer 163 may have a shape that protrudes more than the first bank layer 161 toward the first opening OP1. Accordingly, the side surface 161c of the first bank layer 161 may have a shape recessed inward (e.g., to the first direction X or the second direction Y) from the side surface 163c of the second bank layer 163. Due to this, the second bank layer 163 of the bank structure 160 may include a tip TIP protruding toward the first opening OP1, and an undercut may be formed between bottom of the tip TIP of the second bank layer 163 and the side surface 161c of the first bank layer 161.

In some embodiments, the light emitting layers EL1 through EL3 are formed through a thermal evaporation process. Since the thermal evaporation process is performed in a high vacuum chamber, particles for forming the light emitting layers EL1 through EL3 may move with a relatively greater value of mean free path (i.e., straight movement with a relatively long distance). Accordingly, material deposition may not be smooth below the protruding tip of the bank structure 160. Thus, the deposition process of forming the light emitting layers EL1 through EL3 may be performed so that the materials are deposited in a direction that is not perpendicular to the upper surface of the pixel electrodes AE1 through AE3, for example, in a direction inclined between first direction X and the third direction Z.

In an embodiment, when the angle of the deposition process for forming each of the light emitting layer EL1 through EL3 is defined as a first angle, the deposition process for forming each of the light emitting layers EL1 through EL3 may be performed at an angle of 45 to 50 degrees with respect to the upper surface of the pixel electrode AE1, AE2 or AE3. Accordingly, light emitting layer EL1 through EL3 may be formed to fill an area between the pixel electrodes AE1, AE2 or AE3 and the inorganic pixel defining layer 151, and may be partially formed on the side surface 161c of the first bank layer 161 occluded by the protruding tip TIP of the bank structure 160, but may still be limited.

In some embodiments, the common electrodes CE1 through CE3 may be formed through a sputter process. For example, since the sputter process is performed in a relatively low vacuum compared to the thermal evaporation process, the mean free path of the particles forming the common electrodes CE1 through CE3 may be smaller than the mean free path of the particles forming the light emitting layers EL1 through EL3. Accordingly, the step coverage of the common electrodes CE1 through CE3 may be formed to be higher than the step coverage of the light emitting layers EL1 through EL3, and the common electrodes CE1 through CE3 may be formed to be more in contact with the side surface 161c of the first bank layer 161 than the light emitting layers EL1 through EL3.

Referring to FIG. 8, when dividing the side surface 161c of the first bank layer 161 into a first portion 161c-1 in which the first common electrode CE1 contacts the side surface 161c and a second portion 161c-2 in which the first light emitting layer EL1 contacts the side surface 161c, an area A-CE of the first portion 161c-1 contacting the first common electrode CE1 may be greater than an area A-EL of the second portion 161c-2 contacting the first light emitting layer EL1.

Although only the first emission area EA1 have been described for convenience of description, the disclosure is not limited thereto, and the second emission area EA2 and the third emission area EA3 may include the same structure as the first emission area EA1 in another embodiment. In other words, the bank structure 160 of each of the second emission area EA2 and the third emission area EA3 may include a tip TIP, and each tip TIP may be positioned to protrude toward the first opening OP1.

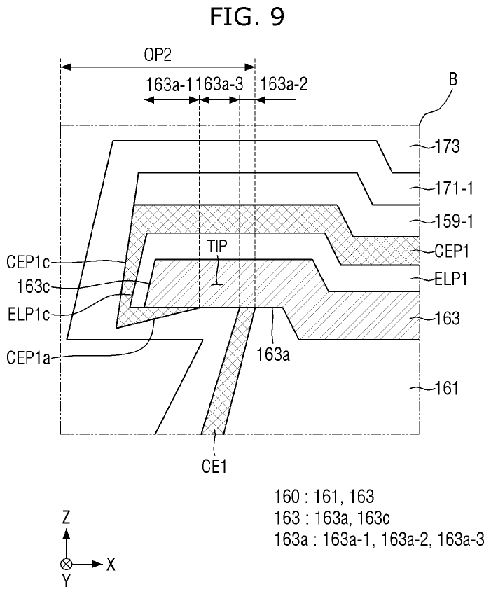

FIG. 9 is an enlarged cross-sectional view of area ‘B’ of FIG. 7.

Referring to FIGS. 6 and 9, since the bank structure 160 includes the protruding tips TIP formed on the second bank layer 163, the light emitting layers EL1 through EL3, the common electrodes CE1 through CE3, and the capping layers 159 formed in the entire display area DA through a deposition process may form layers whose materials are broken between different openings OP1 through OP3 of the bank structure 160. Therefore, patterns including the same materials as the light emitting layers EL1 through EL3, the common electrodes CE1 through CE3, and the capping layers 159 may remain on the bank structure 160.

In some embodiments, the organic patterns ELP1 through ELP3, the electrode patterns CEP1 through CEP3, and the capping patterns 159-1 through 159-3 may be disposed on the bank structure 160 and may surround the emission areas EA1 through EA3 or the first openings OPT. The stacked structure of the organic patterns ELP1 through ELP3, the electrode patterns CEP1 through CEP3, and the capping patterns 159-1 through 159-3 disposed around the emission areas EA1 through EA3 may be partially etched during the fabrication process of the display device 10, and thus the pattern shapes may change. Accordingly, portions of an upper surface of the second bank layer 163 of the bank structure 160 may not be covered by the organic patterns ELP1 through ELP3, the electrode patterns CEP1 through CEP3 and the capping patterns 159-1 through 159-3, and a trench TP (see FIG. 7) may be formed in these portions by the above patterns.

Each of the plurality of organic pattern ELP1, ELP2 and ELP3 may be disposed to partially overlap the second bank layer 163 in a plan view. Each of the plurality of organic pattern ELP1, ELP2 and ELP3 may include the same material as the light emitting layer EL1, EL2 and EL3 of the light emitting element ED1, ED2 and ED3. The first organic pattern ELP1 may include the same material as the first light emitting layer EL1 of the first light emitting element ED1, the second organic pattern ELP2 may include the same material as the second light emitting layer EL2 of the second light emitting element ED2, and the third organic pattern ELP3 may include the same material as the third light emitting layer EL3 of the third light emitting element ED3.

The organic patterns ELP1 through ELP3 may be traces formed by being separated from the light emitting layers EL1 through EL3 because the bank structure 160 includes the tips TIP. The light emitting layers EL1 through EL3 may be formed in the first and second openings OP1 and OP2, and the organic patterns ELP1 through ELP3 may be separated from the light emitting layers EL1 through EL3 by the tips TIP of the bank structure 160.

Referring to FIG. 9, the first organic pattern ELP1 may include a side surface ELP1c of the first organic pattern ELP1 covering the side surface 163c of the second bank layer 163 in an area overlapping the second opening OP2 in a plan view. As described above, the deposition process of forming the light emitting layers EL1 through EL3 may be performed at an angle of 45° to 50° from the upper surface of the pixel electrodes AE1 through AE3. Accordingly, the first organic pattern ELP1 may be positioned while covering the side surface 163c of the second bank layer 163. Although only the first organic pattern ELP1 have been described for convenience of description, the second organic pattern ELP2 and the third organic pattern ELP3 may include the same structure.

The electrode patterns CEP1 through CEP3 may be disposed on the organic patterns ELP1 through ELP3, respectively. The electrode patterns CEP1 through CEP3 may include a first electrode pattern CEP1, a second electrode pattern CEP2, and a third electrode pattern CEP3 including the same materials as the common electrodes CET through CE3 of the light emitting elements ED1 through ED3, respectively. For example, the first electrode pattern CEP1, the second electrode pattern CEP2, and the third electrode pattern CEP3 may be directly disposed on the first organic pattern ELP1, the second organic pattern ELP2, and the third organic pattern ELP3, respectively. The arrangement relationship between the electrode patterns CEP1 through CEP3 and the organic patterns ELP1 through ELP3 may be the same as the arrangement relationship between the light emitting layers EL1 through EL3 of the light emitting elements ED1 through ED3 and the common electrodes CET through CE3. The electrode patterns CEP1 through CEP3 may be traces formed when deposited materials are separated from the common electrodes CET through CE3 because the bank structure 160 includes the tips TIP. In the display device 10, the common electrodes CET through CE3 can be separately formed in different areas by the tips TIP of the bank structure 160 even in a deposition process not using a mask.

As described above, since the common electrodes CE1 through CE3 include a process having a high step coverage, the electrode patterns CEP1 through CEP3 may also have a high step coverage.

Referring to FIG. 9, the first electrode pattern CEP1 may completely cover the first organic pattern ELP1 in an area overlapping the second opening OP2 in a plan view. The first electrode pattern CEP1 may include the side surface CEP1c of the first electrode pattern CEP1 covering the side surface ELP1c of the first organic pattern ELP1, and may include a cover surface CEP1a of the first electrode pattern CEP1 covering one surface of the first organic pattern ELP1 facing the first bank layer 161 and a portion of the first surface 163a of the second bank layer 163.

In some embodiments, in the area overlapping the second opening OP2 in a plan view, the first surface 163a of the second bank layer 163 may include a first portion 163a-1 in contact with the cover surface CEP1a of the first electrode pattern CEP1, a second portion 163a-2 in contact with the first common electrode CE1, and a third portion 163a-3 positioned between the first portion 163a-1 and the second portion 163a-2. The first portion 163a-1 and the second portion 163a-2 may be spaced apart with the third portion 163a-3 interposed therebetween, and the third portion 163a-3 included in the first surface 163a of the second bank layer 163 may be in contact with a first inorganic layer 171-1. Although only the first electrode pattern CEP1 have been described for convenience of description, the second electrode pattern CEP2 and the third electrode pattern CEP3 may include the same structure.

In some embodiments, the capping patterns 159-1 through 159-3 may be disposed on the electrode patterns CEP1 through CPE3, respectively. The capping patterns 159-1 through 159-3 may include the same material as the capping layers 159 disposed on the common electrodes CE1 through CE3. Each of the capping patterns 159-1 through 159-3 may be directly disposed on the electrode patterns CEP1 through CEP3, respectively. The arrangement relationship between the capping patterns 159-1 through 159-3 and the respective electrode patterns CEP1 through CEP3 may be the same as the arrangement relationship of the common electrodes CE1 through CE3 of the respective light emitting elements ED1 through ED3 and the capping layers 159. Such capping patterns 159-1 through 159-3 may be traces formed when the deposited material is not connected to the capping layers 159 and is disconnected as the bank structure 160 includes the tip TIP. The capping patterns 159-1 through 159-3 may not be deposited on the side surface 163c of the second bank layer 163 and may be positioned on the respective electrode patterns CEP1 through CPE3, but the present disclosure is not limited thereto.

The first encapsulation layer 171 may be disposed while covering the light emitting elements ED1 through ED3, a plurality of patterns and the bank structure 160. The first encapsulation layer 171 may include a first inorganic layer 171-1, a second inorganic layer 171-2 and a third inorganic layer 171-3 disposed to correspond to the different emission areas EA1 through EA3, respectively.

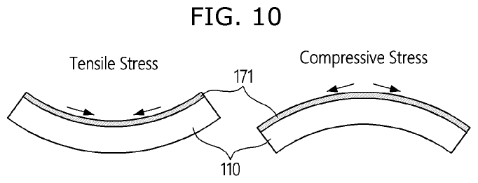

FIG. 10 is a schematic view showing tensile stress and compressive stress of a thin film.

For convenience of description, a structure in which only the first encapsulation layer 171 is included on the substrate 110 is illustrated in FIG. 10.

Referring to FIG. 10, when the first encapsulation layer 171 includes tensile stress, opposite ends of the substrate 110 may be bent toward one side of the third direction Z, that is, the upper surface of the display device 10. Alternatively, when the first encapsulation layer 171 includes compressive stress, opposite ends of the substrate 110 may be bent toward the other side in the third direction Z, that is, the lower surface of the display device 10.

In other words, when the first encapsulation layer 171 includes tensile stress, opposite ends of the first encapsulation layer 171 may be bent toward the one side of the third direction Z, that is, the upper surface of the display device 10. Alternatively, when the first encapsulation layer 171 includes compressive stress, opposite ends of the first encapsulation layer 171 may be bent toward the other side of the third direction Z, that is, the direction in which the substrate 110 is positioned.

The first encapsulation layer 171 may be formed through chemical vapor deposition, and the compressive stress and tensile stress properties may be adjusted according to various factors such as process materials, pressure, and temperature. For example, the first encapsulation layer 171 included in the present embodiment may include compressive stress.

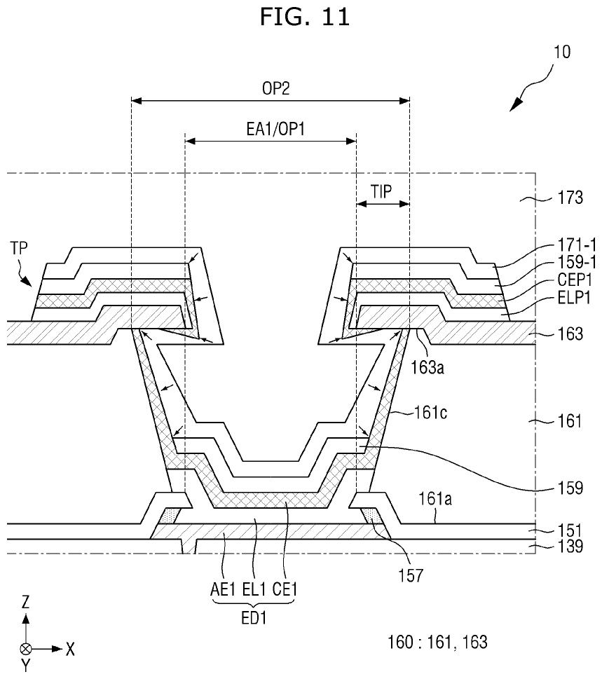

FIG. 11 is a cross-sectional view showing a compressive stress direction of an encapsulation layer in a first emission area of FIG. 6.

Referring to FIG. 11, the first inorganic layer 171-1 including compressive stress may have improved adhesion to lower components in the direction of an arrow. In other words, since the first inorganic layer 171-1 includes compressive stress, the second bank layer 163 and the first common electrode CE1 may maintain high adhesion in the direction of the arrow under the undercut structure formed by the tip TIP of the bank structure 160. Accordingly, poor permeability due to oxygen and moisture introduced from the outside of the display device 10 may be reduced, and reliability of the display device 10 may be improved. Although only the first emission area EA1 and the first inorganic layer 171-1 have been described for convenience of description, the present disclosure is not limited thereto. That is, the second inorganic layer 171-2 positioned in the second emission area EA2 and the third inorganic layer 171-3 positioned in the third emission area EA3 may include the same properties in another embodiment.

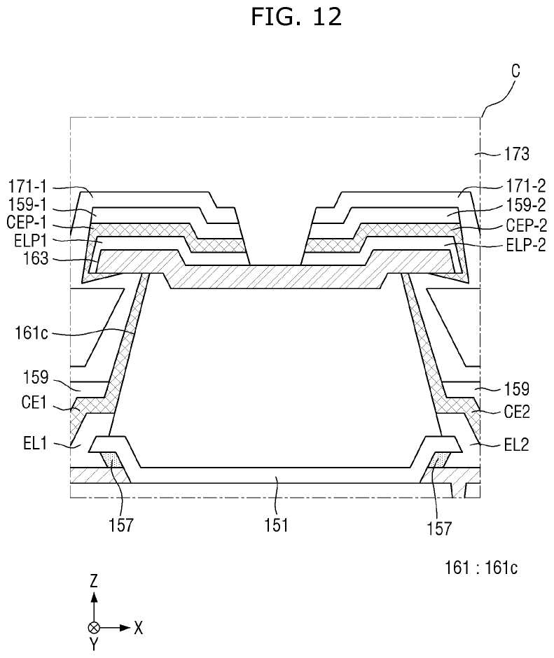

FIG. 12 is an enlarged cross-sectional view of area ‘C’ of FIG. 6.

Referring to FIG. 12, the first inorganic layer 171-1 and the second inorganic layer 171-2 may be partially disposed on the bank structure 160 around the first emission area EA1 and the second emission area EA2, respectively. The shapes of the first inorganic layer 171-1 and the second inorganic layer 171-2 may be formed to completely cover the bank structure 160 and then partially patterned during the manufacturing process. Accordingly, the first inorganic layer 171-1 and the second inorganic layer 171-2 may be disposed to be spaced apart from each other, and the second bank layer 163 of the bank structure 160 may be in direct contact with the second encapsulation layer 173 between the first inorganic layer 171-1 and the second inorganic layer 171-2.

In addition, one side of the side surface 161c of the first bank layer 161 may be covered by the first light emitting layer EL1 and the first common electrode CE1, and the other side of the side surface 161c of the first bank layer 161 may be covered by the second light emitting layer EL2 and the second common electrode CE2.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a first pixel electrode disposed on the substrate;
a pixel defining layer disposed on the substrate and defining a first opening overlapping the first pixel electrode in a plan view;
a bank structure disposed on the pixel defining layer and defining a second opening overlapping the first opening in the plan view;
a first light emitting layer disposed on the first pixel electrode in the first opening;
a first common electrode disposed on the first light emitting layer in the second opening and in contact with the bank structure; and
a first encapsulation layer disposed on the first common electrode and the bank structure,
wherein the bank structure comprises:
a first bank layer disposed on the pixel defining layer and including a conductive material; and
a second bank layer disposed on the first bank layer and including a tip protruding toward the first opening more than a side surface of the first bank layer,
wherein the first common electrode extends along the side surface of the first bank layer and is in contact with one surface of the second bank layer facing the first bank layer.

2. The display device of claim 1,
wherein the side surface of the first bank layer includes a first portion in contact with the first common electrode and a second portion in contact with the first light emitting layer,
wherein an entirety of the side surface of the first bank layer is divided into the first portion in contact with the first common electrode and the second portion in contact with the first light emitting layer.

3. The display device of claim 2,
wherein an area of the first portion of the first bank layer in contact with the first common electrode is greater than an area of the second portion of the first bank layer in contact with the first light emitting layer.

4. The display device of claim 3, further comprising a capping layer completely covering a first portion of the first common electrode overlapping the first opening in the plan view,
wherein in the plan view the capping layer expose a second portion of the first common electrode in the second opening, and
wherein the second portion of the first common electrode exposed by the capping layer contacts the first encapsulation layer.

5. The display device of claim 4,
wherein a thickness of the first bank layer in a thickness direction is greater than a thickness of the second bank layer.

6. The display device of claim 1, further comprising a first organic pattern disposed to surround the first opening on the second bank layer of the bank structure and including a same material as the first light emitting layer, wherein the first organic pattern is spaced apart from the first light emitting layer.

7. The display device of claim 6,
further comprising a first electrode pattern completely covering the first organic pattern in an area overlapping the second opening in the plan view and including a same material as the first common electrode, wherein the first electrode pattern is spaced apart from the first common electrode.

8. The display device of claim 7,
wherein the one surface of the second bank layer overlaps the protruding tip of the bank structure and includes:
a first portion in contact with the first electrode pattern; and
a second portion in contact with the first common electrode,
wherein the first portion and the second portion are spaced apart from each other.

9. The display device of claim 8, wherein the one surface of the second bank layer further includes a third portion disposed between the first portion and the second portion, wherein the third portion is in contact with the first encapsulation layer.

10. The display device of claim 7,
wherein the first encapsulation layer is in contact with and covers both the first common electrode and the first electrode pattern and has a compressive stress.

11. The display device of claim 8,
wherein an absolute value of the compressive stress of the first encapsulation layer ranges from about 100 megapascals (MPa) to about 300 Mpa.

12. The display device of claim 1, further comprising:
a second pixel electrode spaced apart from the first pixel electrode and having the pixel defining layer interposed therebetween;
a second light emitting layer disposed on the second pixel electrode; and
a second common electrode disposed on the second light emitting layer,
wherein the first encapsulation layer further comprises:
a first inorganic layer covering the first common electrode; and
a second inorganic layer covering the second common electrode,
wherein the first inorganic layer and the second inorganic layer are spaced apart from each other.

13. The display device of claim 12, further comprising a second encapsulation layer disposed on the first encapsulation layer,
wherein the second encapsulation layer is in contact with the second bank layer of the bank structure at a portion in which the first inorganic layer and the second inorganic layer are spaced apart from each other.

14. A display device comprising:
a substrate;
a first pixel electrode disposed on the substrate;
a pixel defining layer disposed on the substrate and defining a first opening overlapping the first pixel electrode in a plan view;
a bank structure disposed on the pixel defining layer and defining a second opening overlapping the first opening in the plan view;
a first light emitting layer disposed on the first pixel electrode and in the first opening;
a first common electrode disposed on the first light emitting layer and in contact with the bank structure in a region overlapping the second opening in the plan view;
a first electrode pattern disposed to surround the first opening, disposed on the bank structure and spaced apart from the first common electrode; and
an encapsulation layer disposed on the first common electrode and the first electrode pattern,
wherein the bank structure comprises:
a first bank layer disposed on the pixel defining layer and including a conductive material; and
a second bank layer disposed on the first bank layer and including a tip protruding toward the first opening more than a side surface of the first bank layer,
wherein the first electrode pattern includes a first surface covering a side surface of the second bank layer in the region overlapping the second opening and a second surface covering a bottom surface of the second bank layer facing the first bank layer.

15. The display device of claim 14, further comprising a first organic pattern disposed between the second bank layer and the first electrode pattern,
wherein the first organic pattern includes a third surface disposed between the side surface of the second bank layer and the first surface of the first electrode pattern in the region overlapping the second opening in the plan view.

16. The display device of claim 15,
wherein the first organic pattern is not in contact with the bottom surface of the second bank layer facing the first bank layer.

17. The display device of claim 15,
wherein the first common electrode extends to the bottom surface where the first bank layer and the second bank layer come into contact, and
wherein the first common electrode is in contact with the bottom surface of the second bank layer facing the first bank layer.

18. The display device of claim 14,
wherein the encapsulation layer includes compressive stress and closely adheres to and covers the first common electrode and the first electrode pattern.

19. The display device of claim 18,
wherein the encapsulation layer includes silicon nitride (SiNx), and
wherein an absolute value of the compressive stress of the encapsulation layer ranges from about 100 MPa to about 300 MPa.

20. A display device comprising:
a substrate;
a first pixel electrode disposed on the substrate;
a pixel defining layer disposed on the substrate and defining a first opening overlapping the first pixel electrode in a plan view;
a bank structure disposed on the pixel defining layer and defining a second opening overlapping the first opening in the plan view;
a first light emitting layer disposed on the first pixel electrode and in the first opening;
a first common electrode disposed on the first light emitting layer and in contact with the bank structure in a region overlapping the second opening in the plan view; and
an encapsulation layer disposed on the first common electrode and the bank structure,
wherein the bank structure comprises:
a first bank layer disposed on the pixel defining layer and includes a conductive material layer; and
a second bank layer disposed on the first bank layer and including a tip protruding toward the first opening more than a side surface of the first bank layer,
wherein the encapsulation layer has a compressive stress and closely adheres to and covers the first common electrode and the protruding tip of the bank structure.
